(19) United States
(12) Patent Application Publication
(10) Pub. No.: US 2023/0107486 A1
(43) Pub. Date: Apr. 6, 2023

(54) LIGHT SOURCE MODULE

(71) Applicant: Ming-Teng KUO, Tainan City (TW)

(72) Inventor: Ming-Teng KUO, Tainan City (TW)

(21) Appl. No.: 17/694,239

(22) Filed: Mar. 14, 2022

(30) Foreign Application Priority Data
Oct. 3, 2021 (TW) 110136799

(51) Int. Cl. H01L 33/62; H01L 33/38

(52) U.S. Cl. CPC H01L 33/62; H01L 33/387

(57) ABSTRACT

A light source module including a substrate, a first copper trace, a second copper trace, a third copper trace, a first light emitting unit, and a second light emitting unit is provided. The second light emitting unit is electrically connected to the first light emitting unit. The first light emitting unit and the second light emitting unit are disposed in parallel along a first direction and respectively have a positive electrode and a negative electrode opposite to each other in a second direction, which is perpendicular to the first direction. The negative electrode of the first light emitting unit is connected to the first copper trace, the positive electrode of the second light emitting unit is connected to the second copper trace, and the positive electrode of the first light emitting unit and the negative electrode of the second light emitting unit are connected to the third copper trace.

### CROSS REFERENCE TO RELATED APPLICATION

This application claims the benefit of Taiwan Patent Application Serial No. 110136799 filed on Oct. 3, 2021, which is incorporated herein by reference.

### BACKGROUND OF THE INVENTION

### 1. Field of the Invention

The present invention relates to a light source module. Specifically, the present invention relates to a light source module with increased area of the copper trace at the connection between the light emitting units.

### 2. Description of Related Art

Light emitting diodes (LEDs) have the advantages of power saving, high luminous efficiency, long service life, and quick response, and are becoming more and more popular in various light source modules. In terms of automotive lighting, with the development of electric vehicles in recent years, it is an important issue for the development of electric vehicles to improve the power consumption efficiency or reduce power loss of all electrical equipment (especially automotive lighting fixtures).

As shown in FIG. 1A to FIG. 1C, in order to have a better light intensity for the light source module used in automotive lighting fixtures, the light emitting unit 19 (e.g., the LEDs) has the dies tightly arranged. The circuit layout of the existing light source module is that the positive and negative electrodes of each light emitting unit 19 (die) are arranged in the same direction, thereby the area of the copper trace CT at the connection of the two light emitting units 19 is small. However, the temperature of the light emitting unit will rise sharply when using. If the area of the copper trace CT at the connection of the light emitting unit 19 is too small, the light emitting unit will not be able to effectively dissipate heat which results in serious heat accumulation in the light source zone between the light emitting units. In the end, the light emitting unit has serious light attenuation, which greatly reduces the luminous efficiency of the light emitting unit and even damaged the light emitting unit. In addition, more light emitting units 19 used in the light source module will result in more severe heat accumulation and light attenuation.

Accordingly, how to increase the area of the copper trace at the junction of the light emitting unit die when laying out the light source module is a technical problem that the industry needs to solve urgently.

### SUMMARY OF THE INVENTION

An objective of the present invention is to provide a light source module, the positive electrode and the negative electrode of the light emitting units (die) are disposed in opposite directions to make the position of the copper trace at the connection between the light emitting units is no longer limited to be arranged between the positive electrode copper trace and the negative electrode copper trace of the light source module. The area of the copper trace at the connection between the light emitting units can be greatly increased, and thus the heat generated by the light emitting units can not only be conducted downwards, but also can be outwardly conducted on the same plane. Therefore, the light source module of the present invention can reduce the heat accumulation effect and light attenuation of the light source between the light emitting units, and improve the service life and optical performance of the light emitting units.

To achieve the aforesaid objective, the present invention discloses a light source module which includes a substrate, a ceramic substrate, a first copper trace, a second copper trace, at least one third copper trace, a first light emitting unit, and a second light emitting unit. The first copper trace is disposed on the substrate. The second copper trace is disposed on the substrate. The at least one third copper trace is disposed on the substrate. The first light emitting unit is disposed on the substrate. The second light emitting unit is disposed on the substrate and electrically connected to the first light emitting unit. The first light emitting unit and the second light emitting unit are parallel in a first direction, both of the first light emitting unit and the second light emitting unit have a positive electrode and a negative electrode opposite to each other in a second direction. The second direction is perpendicular to the first direction. The negative electrode of the first light emitting unit is connected to the first copper trace, the positive electrode of the second light emitting unit is connected to the second copper trace, and the positive electrode of the first light emitting unit and the negative electrode of the second light emitting unit are connected to the at least one third copper trace.

The positive electrode and the negative electrode of the first light emitting unit are respectively adjacent to the negative electrode and the positive electrode of the second light emitting unit.

In one embodiment, the light source module further includes a third light emitting unit, the third light emitting unit has a positive electrode and a negative electrode, and the negative electrode of the third light emitting unit is adjacent to the positive electrode of the first light emitting unit and is connected to the positive electrode of the first light emitting unit via one of the at least one third copper trace, the positive electrode of the third light emitting unit is adjacent to the negative electrode of the second light emitting unit and is connected to the negative electrode of the second light emitting unit via the other third copper trace of the at least one third copper trace.

In other embodiments, the light source module further includes a third light emitting unit, the third light emitting unit has an positive electrode and a negative electrode, and the negative electrode of the third light emitting unit is adjacent to the negative electrode of the second light emitting unit and is connected to the negative electrode of the second light emitting unit and the positive electrode of the first light emitting unit via the at least one third copper trace, and the positive electrode of the third light emitting unit is adjacent to the positive electrode of the second light emitting unit and is connected to the positive electrode of the second light emitting unit via the second copper trace. In other embodiments, the light source module further includes a third light emitting unit, the third light emitting unit having an positive electrode and a negative electrode, and the negative electrode of the third light emitting unit is adjacent to the positive electrode of the second light emitting unit and is connected to the negative electrode of the first light emitting unit via the first copper trace, the positive electrode of the third light emitting unit is adjacent to the negative electrode of the second light emitting unit and is connected to the negative electrode of the second light emitting unit and the positive electrode of the first light emitting unit via the at least one third copper trace.

In other embodiments, the negative electrode of the third light emitting unit is adjacent to the negative electrode of the first light emitting unit, and the positive electrode of the third light emitting unit is adjacent to the positive electrode of the first light emitting unit.

The first light emitting unit, the second light emitting unit, and the third light emitting unit are staggered in the first direction.

The at least one third copper trace is partially staggered with at least one of the first copper trace and the second copper trace in the second direction.

In one embodiment, a total area of the at least one third copper trace is greater than one of a first area of the first copper trace and a second area of the second copper trace.

In other embodiments, the total area of the at least one third copper trace is greater than a sum of the first area of the first copper trace and a second area of the second copper trace.

When the adjacent light emitting units are arranged in a reverse direction, a first light attenuation of each of the light emitting units is smaller than a second light attenuation of each of the light emitting unit when the adjacent light emitting units are arranged in an identical direction.

The first copper trace is a negative electrode of the light source module, and the second copper trace is a positive electrode of the light source module.

The detailed technology and preferred embodiments implemented for the present invention are described in the following paragraphs accompanying the appended drawings for people skilled in this field to well appreciate the features of the claimed invention.

### BRIEF DESCRIPTION OF THE DRAWINGS

FIG. 1A to 1C are schematic views of the circuit layout of the conventional light source module;

FIG. 2 is a schematic view of the circuit layout of the light source module according to the present invention;

FIG. 3 is a schematic view of the circuit of the light emitting units according to the present invention;

FIG. 4 is a schematic view of the circuit layout of the light source module according to the present invention;

FIG. 5 is a schematic view of the circuit of the light emitting units according to the present invention;

FIG. 6 is a schematic view of the circuit layout of the light source module according to the present invention; and

FIG. 7 is a schematic view of the circuit of the light emitting units according to the present invention.

### DETAILED DESCRIPTION OF THE PREFERRED EMBODIMENT

Reference will now be made in detail to the present embodiments of the invention, examples of which are illustrated in the accompanying drawings, and are not intended to limit the present invention, applications or particular implementations described in these embodiments. Wherever possible, the same reference numbers are used in the drawings and the description to refer to the same or like parts. It shall be appreciated that, in the following embodiments and the attached drawings, elements unrelated to the present invention are omitted from depiction; and dimensional relationships among individual elements in the attached drawings are provided only for ease of understanding, but not to limit the actual scale.

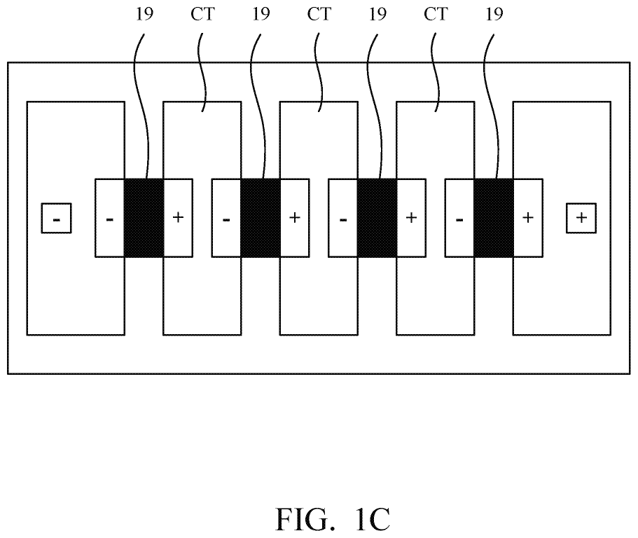

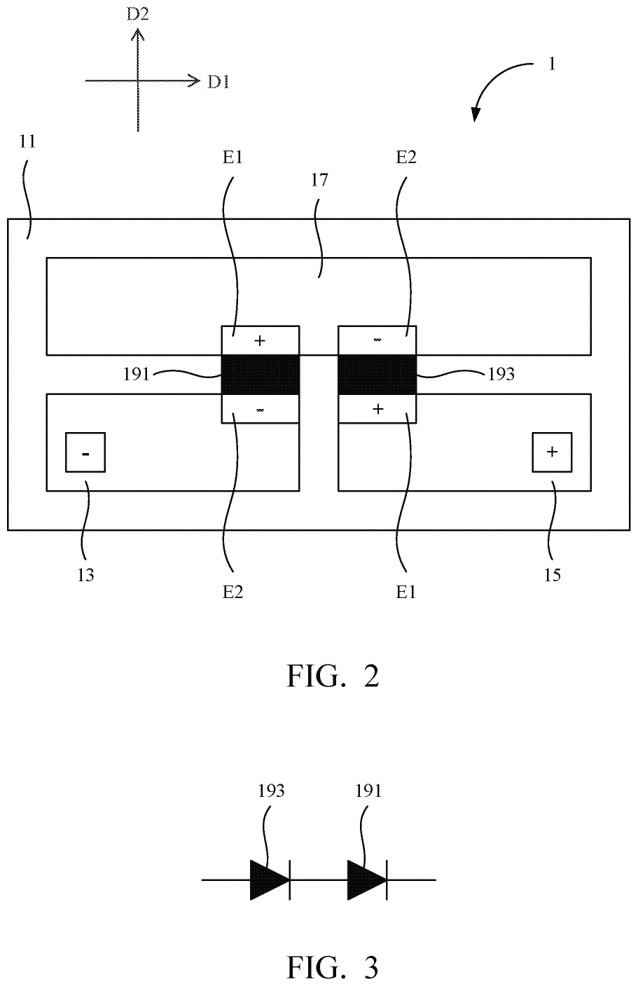

Reference is made to FIG. 2 and FIG. 3. FIG. 2 is a schematic view of the circuit layout of the light source module according to the present invention. The light source module 1 includes a substrate 11, a first copper trace 13, a second copper trace 15, at least one third copper trace 17, a first light emitting unit 191, and a second light emitting unit 193. The substrate 11 may be a ceramic substrate, a metal substrate, or other kinds of substrate, but not limited thereto. The first copper trace 13, the second copper trace 15, the third copper trace 17, the first light emitting unit 191, and the second light emitting unit 193 are all disposed on the substrate 11.

The first light emitting unit 191 and the second light emitting unit 193 may be light-emitting diode (LED) modules, but not limited thereto. The second light emitting unit 193 is electrically connected to the first light emitting unit 191, and the schematic view of the circuit is shown in FIG. 3.

Different from the conventional light source module which arranges the light emitting units in the same direction, in the circuit layout of the light source module 1 of the present invention, the first light emitting unit 191 and the second light emitting unit 193 are arranged in parallel. In detail, with reference to FIG. 2, the first light emitting unit 191 and the second light emitting unit 193 are disposed in parallel along a first direction D1. Both the first light emitting unit 191 and the second light emitting unit 193 have two coupling points which are a positive electrode E1 and a negative electrode E2. The positive electrode E1 and the negative electrode E2 are opposite to each other in a second direction D2. The second direction D2 is perpendicular to the first direction D1.

Please refer to FIG. 2 again. The negative electrode E2 of the first light emitting unit 191 is connected to the first copper trace 13, and the positive electrode E1 of the second light emitting unit 193 is connected to the second copper trace 15. Therefore, the first copper trace 13 is the negative electrode of the light source module 1, and the second copper trace 15 is the positive electrode of the light source module 1. The other coupling points of the light emitting units that are not connected to the first copper trace 13 and the second copper trace 15 are all connected to the third copper trace 17, that is, the positive electrode E1 of the first light emitting unit 191 and the negative electrode E2 of the second light emitting unit 193 is connected to the third copper trace 17. To be more specific, when the light emitting units are connected in series, the positive electrode

E1 of one of the two adjacent light emitting units is connected to the negative electrode E2 of the other, and the third copper trace 17 is the coupling area between the two light emitting units which are connected in series. Therefore, as the number of light emitting units increases, the number of third copper traces 17 also increases.

For example, reference is made to FIG. 2 and FIG. 3. When the number of light emitting units is two, the negative electrode E2 of the first light emitting unit 191 is connected to the first copper trace 13, the positive electrode E1 of the first light emitting unit 191 is connected to the negative electrode E2 of the second light emitting unit 193 via the third copper trace 17, and the positive electrode E1 of the second light emitting unit 193 is connected to the second copper trace 15. In this case, the number of the third copper trace 17 is only one.

It can be seen from FIG. 2 that the third copper trace 17 is partially staggered with at least one of the first copper trace 13 and the second copper trace 15 in the second direction D2. Since the positive electrodes El and the negative electrodes E2 of the adjacent first light emitting unit 191 and the second light emitting unit 193 are arranged in opposite directions to each other, the area of the third copper trace 17 connecting the adjacent light emitting units can be greatly increased comparing with the conventional technology. When the first light emitting unit 191 and the second light emitting unit 193 emit light, heat generated from the first light emitting unit 191 and the second light emitting unit 193 can be conducted more quickly.

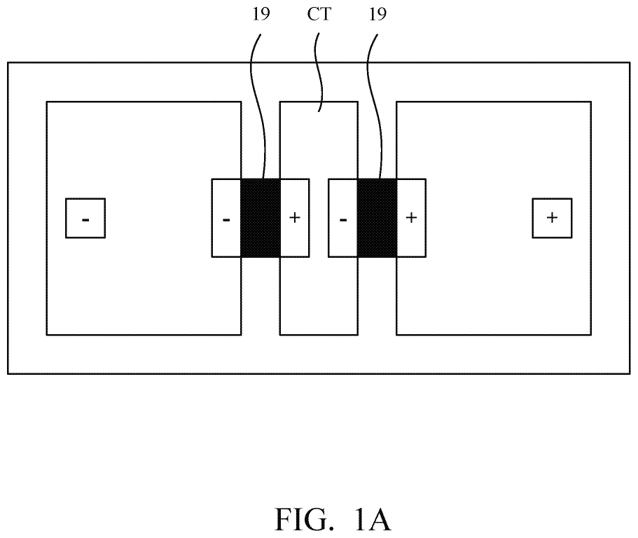

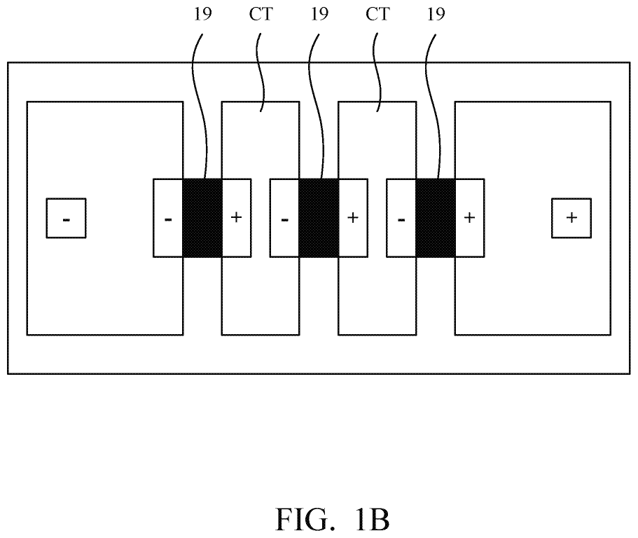

In the present invention, since the area of the third copper trace 17 is greatly increased, when the heat generated from the first light emitting unit 191 and the second light emitting unit 193 is effectively dissipated and the accumulated heat is reduced, the light attenuation of the first light emitting unit 191 and the second light emitting unit 191 is also reduced. In other words, when the adjacent light emitting units are arranged in the reverse direction as shown in FIG. 2, the first light attenuation of each light emitting unit is smaller than the second light attenuation of the adjacent light emitting units when they are arranged in the same direction as shown in FIG. 1.

In addition, if the space on the substrate is sufficient, the total area of the third copper trace 17 can be designed to be larger than the first area of the first copper trace 13 or the second area 15 of the second copper trace.

Alternatively, the total area of the third copper trace 17 can be designed to be larger than the sum of the first area of the first copper trace 13 and the second area of the second copper trace 15, which depends on the size of the substrate.

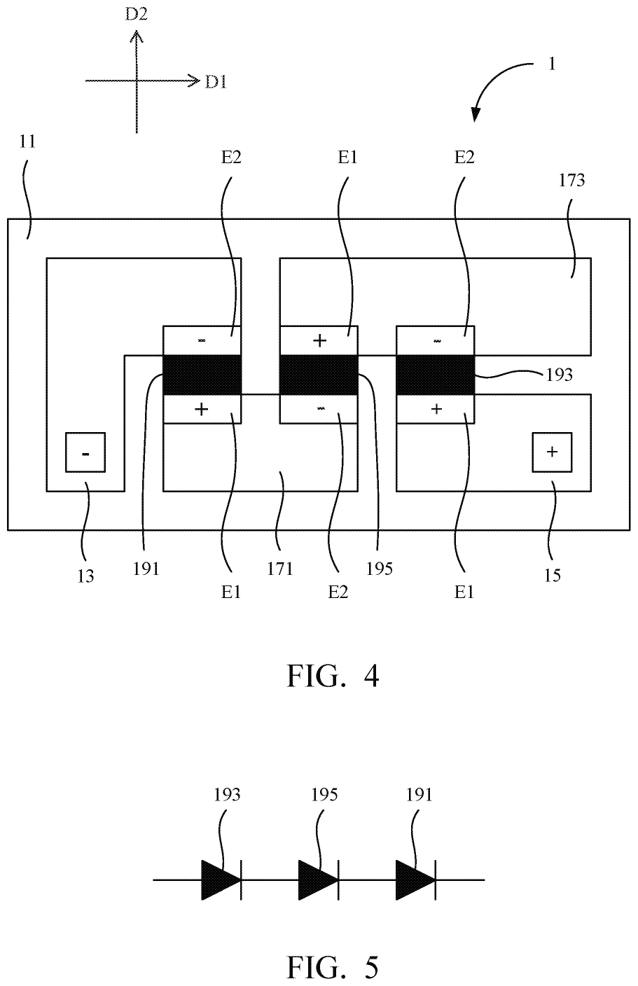

For another example, reference is made to FIG. 4 and FIG. 5. FIG. 4 is a schematic view of the circuit layout of the light source module according to the present invention. FIG. 5 is a schematic view of the circuit of the light emitting units of FIG. 4. In FIG. 4 and FIG. 5, the light source module 1 further includes a third light emitting unit 195, that is, the number of light emitting units is three. The negative electrode E2 of the first light emitting unit 191 is connected to the first copper trace 13, the positive electrode E1 of the second light emitting unit 193 is connected to the second copper trace 15, and the negative electrode E2 of the third light emitting unit 195 is adjacent to the positive electrode E1 of the first light emitting unit 191 and is connected to the positive electrode E1 of the first light emitting unit 191 via the third copper trace 171. The positive electrode E1 of the third light emitting unit 195 is adjacent to the negative electrode E2 of the second light emitting unit 193 and is connected to the negative electrode E2 of the second light emitting unit 193 via the third copper trace 173. In this case, the light source module 1 includes two third copper traces 171 and 173 in total.

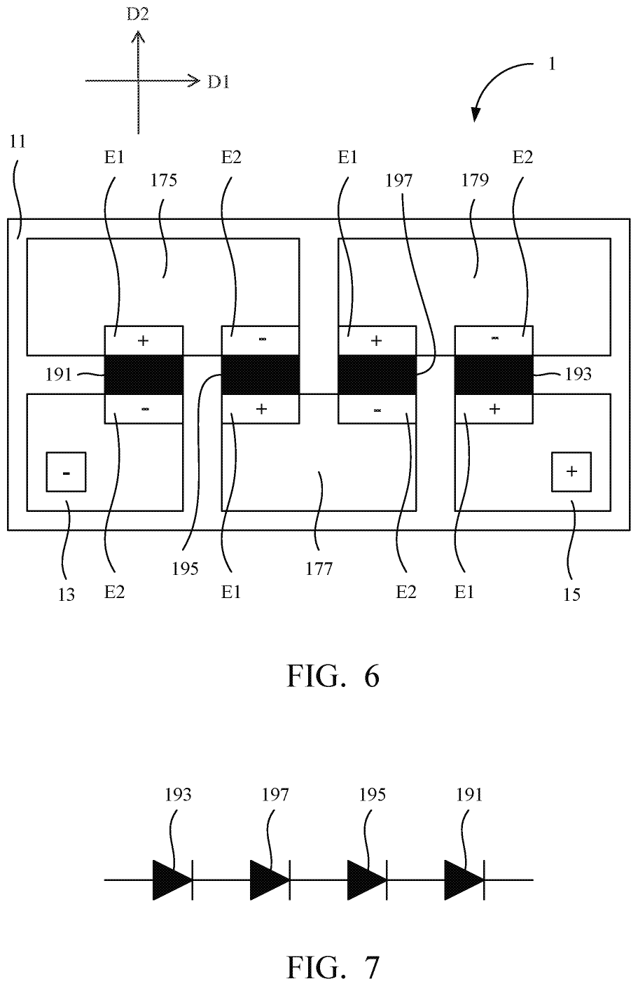

For another example, reference is made to FIG. 6 and FIG. 7. FIG. 6 is a schematic view of the circuit layout of the light source module according to the present invention. FIG. 7 is a schematic view of the circuit of the light emitting units of FIG. 6. In FIG. 6 and FIG. 7, the light source module 1 further includes a fourth light emitting unit 197, that is, the number of light emitting units is four. The negative electrode E2 of the first light emitting unit 191 is connected to the first copper trace 13, and the positive electrode E1 of the second light emitting unit 193 is connected to the second copper trace 15. The positive electrode E1 of the first light emitting unit 191 is connected to the negative electrode E2 of the third light emitting unit 195 via the third copper trace 175. The positive electrode E1 of the third light emitting unit 195 is connected to the negative electrode E2 of the fourth light emitting unit 197 via the third copper trace 177. The positive electrode E1 of the fourth light emitting unit 197 is connected to the negative electrode E2 of the second light emitting unit 193 via the third copper trace 179. In this case, the light source module 1 includes three third copper traces 175, 177 and 179.

It shall be noted that the foregoing description takes the light emitting units connecting in series with each other as examples. In order to maximize the area of the third copper trace as much as possible, in the case of series connection, regardless of the number of light emitting units, the positive electrode E1 and the negative electrode E2 of each adjacent light emitting unit are arranged opposite to each other. In other words, among the two adjacent light-emitting units, the positive electrode E1 and the negative electrode E2 of one of them are respectively adjacent to the negative electrode E2 and the positive electrode E1 of the other of them. In other embodiments, when the light emitting units are connected in parallel, according to various ways of circuit layout, the positive electrode E1 of one of the two adjacent light emitting units may be adjacent to the positive electrode E1 or the negative electrode E2 of the other.

Specifically, taking the case where the light source module includes three light emitting units (i.e., the first light emitting units 191, the second light emitting unit 193, and the third light emitting unit 195) as an illustration, when the second light emitting unit 193 and the third light emitting unit 195 are connected in parallel, and the connected second light emitting unit 193 and third light emitting unit 195 further connected with the first light emitting unit 191 in series, the connection of the light emitting units is that the negative electrode E2 of the third light emitting unit 195 is connected to the negative electrode E2 of the second light emitting unit 193 and the positive electrode E1 of the first light emitting unit 191, and the positive electrode E1 of the third light emitting unit 195 is connected to the positive electrode E1 of the second light emitting unit 193.

The circuit layout can be designed to make the first light emitting unit 191, the second light emitting unit 193, and the third light emitting unit 195 be arranged side by side along the first direction D1, and the second light emitting unit 193 is disposed between the first light emitting unit 191 and the third light emitting unit 195. The negative electrode E2 of the third light emitting unit 195 is adjacent to the negative electrode E2 of the second light emitting unit 193 and is connected to the negative electrode E2 of the second light emitting unit 193 and the positive electrode E1 of the first light emitting unit 191 via the third copper trace 17. The positive electrode E1 of the third light emitting unit 195 is adjacent to the positive electrode E1 of the second light emitting unit 193 and is connected to the positive electrode E1 of the second light emitting unit 193 via the second copper trace 15, and the negative electrode E2 of the first light emitting unit 191 is connected to the first copper trace 13. In this case, the number of the third copper trace 17 of the light source module 1 is one, and the area of the third copper trace 17 is greater than the area of the first copper trace 13 and the area of the second copper trace 15.

In other embodiments, the third light emitting unit 195 and the first light emitting unit 191 are connected in parallel, and the connected third light emitting unit 195 and first light emitting unit 191 further connected with the second light emitting unit 193 in series. The connection of the light emitting units is that the negative electrode E2 of the third light emitting unit 195 is connected to the negative electrode E2 of the first light emitting unit 195, and the positive electrode E1 of the third light emitting unit 195 is connected to the positive electrode E1 of the first light emitting unit 191 and the negative electrode E2 of the second light emitting unit 193.

There are at least two ways of circuit layout for the light source module. The first circuit layout is to dispose the first light emitting unit 191, the second light emitting unit 193, and the third light emitting unit 195 side by side along the first direction D1, and the second light emitting unit 193 is disposed between the first light emitting unit 191 and the third light emitting unit 195. The negative electrode E2 of the third light emitting unit 195 is adjacent to the positive electrode E1 of the second light emitting unit 193 and is connected to the negative electrode E2 of the first light emitting unit 191 via the first copper trace 13. The positive electrode E1 of the third light emitting unit 195 is adjacent to the negative electrode E2 of the second light emitting unit 193, and is connected to the negative electrode E2 of the second light emitting unit 193 and the positive electrode E1 of the first light emitting unit 191 via the third copper trace 17. The positive electrode E2 of the second light emitting unit 193 is connected to the second copper trace 15. In this case, the number of the third copper trace 17 of the light source module 1 is one, and the area where the third copper trace 17 is coupled to the light emitting units is enlarged. Preferably, the area of the third copper trace 17 may be smaller than the area of the first copper trace 13, and greater than the area of the second copper trace 15.

The second circuit layout is to dispose the first light emitting unit 191, the second light emitting unit 193, and the third light emitting unit 195 side by side along the first direction D1, and the third light emitting unit 195 is disposed between the second light emitting unit 193 and the first light emitting unit 191. The negative electrode E2 of the third light emitting unit 195 is adjacent to the negative electrode E2 of the first light emitting unit 191 and the positive electrode E1 of the second light emitting unit 193 and is connected to the negative electrode E2 of the first light emitting unit 191 via the first copper trace 13. The positive electrode E1 of the third light emitting unit 195 is adjacent to the positive electrode E1 of the first light emitting unit 191 and the negative electrode E2 of the second light emitting unit 193, and is connected to the negative electrode E2 of the second light emitting unit 193 and the positive electrode E1 of the first light emitting unit 191 via the third copper trace 17. The positive electrode E2 of the second light emitting unit 193 is connected to the second copper trace 15. In this case, the number of the third copper trace 17 of the light source module 1 is one, and the area where the third copper trace 17 is coupled to the light emitting units is enlarged. Preferably, the area of the third copper trace 17 may be greater than the area of the first copper trace 13 and the area of the second copper trace 15.

In addition, in other embodiments, the second circuit layout may also designed to dispose the first light emitting unit 191 between the second light emitting unit 193 the connected third light emitting unit 195. Thus, the negative electrode E2 of the third light emitting unit 195 is only adjacent to the negative electrode E2 of the first light emitting unit 191, and the positive electrode E1 of the third light emitting unit 195 is only adjacent to the positive electrode E1 of the first light emitting unit 191.

The aforementioned light emitting units are aligned arrangement. In other embodiments, the light emitting units can also be staggered in the first direction. After matching with the reflective surface of the lamp, the light emitting unit will have a good illuminance projection effect.

According to the above, the present invention improves the circuit layout of the light source module by disposing the positive electrode and the negative electrode of the light emitting unit in opposite direction. Therefore, the area of the copper trace at the connection between the light emitting units can be greatly increased, and thus the heat generated from the light emitting units can not only be conducted downwards, but also can be outwardly conducted on the same plane, so as to reduce the serious heat accumulation effect and the light attenuation of the light emitting units, and to improve the service life and optical performance of the light emitting units.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims

1. A light source module, comprising:
a substrate;
a first copper trace being disposed on the substrate;
a second copper trace being disposed on the substrate;
at least one third copper trace being disposed on the substrate;
a first light emitting unit being disposed on the substrate; and
a second light emitting unit being disposed on the substrate and electrically connected to the first light emitting unit;
wherein, the first light emitting unit and the second light emitting unit are parallel in a first direction, both of the first light emitting unit and the second light emitting unit have a positive electrode and a negative electrode opposite to each other in a second direction, the second direction is perpendicular to the first direction, the negative electrode of the first light emitting unit is connected to the first copper trace, the positive electrode of the second light emitting unit is connected to the second copper trace, and the positive electrode of the first light emitting unit and the negative electrode of the second light emitting unit are connected to the at least one third copper trace.

2. The light source module as claimed in claim 1, wherein the positive electrode and the negative electrode of the first light emitting unit are respectively adjacent to the negative electrode and the positive electrode of the second light emitting unit.

3. The light source module as claimed in claim 1, further comprising a third light emitting unit, the third light emitting unit having a positive electrode and a negative electrode, wherein the negative electrode of the third light emitting unit is adjacent to the positive electrode of the first light emitting unit and is connected to the positive electrode of the first light emitting unit via one of the at least one third copper trace, and the positive electrode of the third light emitting unit is adjacent to the negative electrode of the second light emitting unit and is connected to the negative electrode of the second light emitting unit via the other third copper trace of the at least one third copper trace.

4. The light source module as claimed in claim 2, further comprising a third light emitting unit, the third light emitting unit having an positive electrode and a negative electrode, wherein the negative electrode of the third light emitting unit is adjacent to the negative electrode of the second light emitting unit and is connected to the negative electrode of the second light emitting unit and the positive electrode of the first light emitting unit via the at least one third copper trace, and the positive electrode of the third light emitting unit is adjacent to the positive electrode of the second light emitting unit and is connected to the positive electrode of the second light emitting unit via the second copper trace.

5. The light source module as claimed in claim 2, further comprising a third light emitting unit, the third light emitting unit having an positive electrode and a negative electrode, wherein the negative electrode of the third light emitting unit is adjacent to the positive electrode of the second light emitting unit and is connected to the negative electrode of the first light emitting unit via the first copper trace, and the positive electrode of the third light emitting unit is adjacent to the negative electrode of the second light emitting unit and is connected to the negative electrode of the second light emitting unit and the positive electrode of the first light emitting unit via the at least one third copper trace.

6. The light source module as claimed in claim 5, wherein the negative electrode of the third light emitting unit is adjacent to the negative electrode of the first light emitting unit, and the positive electrode of the third light emitting unit is adjacent to the positive electrode of the first light emitting unit.

7. The light source module as claimed in claim 3, wherein the first light emitting unit, the second light emitting unit, and the third light emitting unit are staggered in the first direction.

8. The light source module as claimed in claim 1, wherein the at least one third copper trace is partially staggered with at least one of the first copper trace and the second copper trace in the second direction.

9. The light source module as claimed in claim 8, wherein a total area of the at least one third copper trace is greater than one of a first area of the first copper trace and a second area of the second copper trace.

10. The light source module as claimed in claim 8, wherein a total area of the at least one third copper trace is greater than a sum of a first area of the first copper trace and a second area of the second copper trace.

11. The light source module as claimed in claim 8, wherein when the adjacent light emitting units are arranged in a reverse direction, a first light attenuation of each of the light emitting units is smaller than a second light attenuation of each of the light emitting unit when the adjacent light emitting units are arranged in an identical direction.

12. The light source module as claimed in claim 8, wherein the first copper trace is a negative electrode of the light source module, and the second copper trace is a positive electrode of the light source module.
